(19) United States
(12) Patent Application Publication
(10) Pub. No.: US 2022/0216085 A1
(43) Pub. Date: Jul. 7, 2022

(54) ELECTROSTATIC CHUCK AND METHOD FOR MANUFACTURING THE SAME

(71) Applicant: INDUSTRIAL TECHNOLOGY RESEARCH INSTITUTE, Hsinchu (TW)

(72) Inventors: Yung-Hsiang HUANG, Taipei City (TW); Wei-Cheng TANG, Hsinchu City (TW); Yi-Che SU, Zhubei City (TW); Wen-Pin CHUANG, Hsinchu City (TW); Su-Mei CHEN WEI, Hsinchu City (TW); Ya-Tin YU, New Taipei City (TW); Yun-Shan HUANG, Zhunan Township (TW)

(73) Assignee: INDUSTRIAL TECHNOLOGY RESEARCH INSTITUTE, Hsinchu (TW)

(21) Appl. No.: 17/383,679

(22) Filed: Jul. 23, 2021

(30) Foreign Application Priority Data
Jan. 7, 2021 (TW) 110100634

(51) Int. Cl. H01L 21/683; C04B 41/45; C01G 23/04; C04B 35/10; C04B 35/581

(52) U.S. Cl. CPC H01L 21/6833; C04B 41/4523; C01P 2006/40; C04B 35/10; C04B 35/581; C01G 23/04

(57) ABSTRACT

An electrostatic chuck is provided, the electrostatic chuck includes a base; and an insulating layer, an electrode layer, a first dielectric layer, and a second dielectric layer sequentially stacked on the base. The first dielectric layer is aluminum oxide (Al₂O₃) or aluminum nitride (AlN). A material of the second dielectric layer is different from a material of the first dielectric layer, and the second dielectric layer includes titanium element, IVA group element, and oxygen element.

This application claims the benefit of Taiwan application Serial No. 110100634, filed Jan. 7, 2021, the subject matter of which is incorporated herein by reference.

### TECHNICAL FIELD

The technical field relates to an electrostatic chuck and a method for manufacturing the same,

### BACKGROUND

In recent years, the development of the semiconductor industry is getting more and more important. In the various semiconductor related equipment, the electrostatic chuck is one of the most widely used system components. For example, in each of the semiconductor processes (such as the deposition process, the ion implantation process, the dry etching process and the photolithography process), the electrostatic chuck is used to hold, fix and move the wafer. However, the high temperature and the long duration of vacuum state in some semiconductor processes may cause the clamping force of the electrostatic chuck to deteriorate and may also shorten the lifespan of the electrostatic chuck or may even interrupt the semiconductor process. Therefore, it has become a prominent task for the industry to provide an electrostatic chuck capable of preventing the above problems.

### SUMMARY

According to one embodiment of the present disclosure, an electrostatic chuck is provided. The electrostatic chuck includes a base and an insulating layer, an electrode layer, a first dielectric layer and a second dielectric layer sequentially stacked on the base. The first dielectric layer is formed of aluminum oxide (Al₂O₃) or aluminum nitride (AlN). The material of the second dielectric layer is different from that of the first dielectric layer, and the second dielectric layer includes titanium a group IVA element and oxygen.

According to another embodiment of the present disclosure, a method for manufacturing an electrostatic chuck is provided. The method includes the following steps. Firstly, a base is provided. Next, an insulating layer and an electrode layer are sequentially formed and stacked on the base. Then, a first dielectric layer is formed on the insulating layer by using a thermal spraying process. After that, a second dielectric layer is formed on the first dielectric layer by using a sol-gel process. The first dielectric layer is formed of aluminum oxide (Al₂O₃) or aluminum nitride (AlN). The material of the second dielectric layer is different from that of the first dielectric layer, and the second dielectric layer includes titanium, a group IVA element and oxygen.

The above and other aspects of the disclosure will become better understood with regard to the following detailed description of the preferred but non-limiting embodiment(s). The following description is made with reference to the accompanying drawings.

### BRIEF DESCRIPTION OF THE DRAWINGS

FIG. 1 is a cross-sectional view of an electrostatic chuck according to an embodiment of the present disclosure.

FIGS. 2A-2C are processes of a method for manufacturing an electrostatic chuck according to an embodiment of the present disclosure.

FIGS. 3A-3C are processes of a manufacturing method corresponding to a part of the second dielectric layer of FIG. 2A.

FIG. 4 is a schematic diagram of an assembly equipment for testing the electrostatic clamping force of an electrostatic chuck.

### DETAILED DESCRIPTION OF THE DISCLOSURE

A number of implementations of the present disclosure are disclosed below with reference to accompanying drawings. It should be noted that the structure and description of the implementations of the present disclosure are for exemplary purpose only, not for limiting the scope of protection of the present disclosure. Although the present disclosure does not illustrate all possible embodiments, a person ordinary skilled in the technology field can make necessary modifications or adjustments to fit actual needs without departing from the spirit and scope of the present disclosure.

Moreover, similar/identical designations are used to indicate similar/identical elements of the embodiments. Also, the accompanying drawings are simplified such that the embodiments can be more dearly described, and dimension scales used in the accompanying drawings are not based on actual proportion of the product, and therefore are not for limiting the scope of protection of the present disclosure.

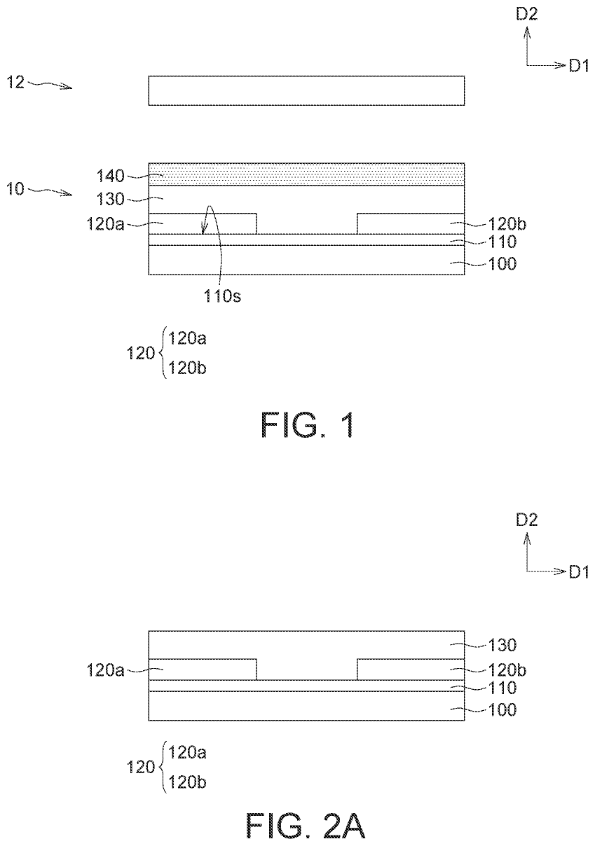

FIG. 1 is a cross-sectional view of an electrostatic chuck 10 according to an embodiment of the present disclosure.

Refer to FIG. 1. The electrostatic chuck 10 can be used to hold, fix or move an object 12. The object 12 such as a wafer, glass or other suitable objects. According to an embodiment, the electrostatic chuck 10 comprises a base 100 and an insulating layer 110, an electrode layer 120, a first dielectric layer 130 and a second dielectric layer 140 sequentially stacked (such as vertical stacking) on the base 100. The electrode layer 120 comprises a first electrode 120a and a second electrode 120b. In an embodiment, a positive voltage and a negative voltage are respectively applied to the first electrode 120a and the second electrode 120b to make the electrostatic chuck 10 generate induced charges to hold, fix or move the object 12. In other embodiment, a negative voltage and a positive voltage are respectively applied to the first electrode 120a and the second electrode 120b.

In some embodiments, the insulating layer 110 has an upper surface 110s with which the electrode layer 120 and the first dielectric layer 130 can directly contact. The extending direction of the upper surface 110s is parallel to the first direction D1, and the normal direction of the upper surface 110s is parallel to the second direction D2. The electrode layer 120 is interposed between the insulating layer 110 and the first dielectric layer 130, and the first dielectric layer 130 is interposed between the electrode layer 120 and the second dielectric layer 140. That is, the second dielectric layer 140 and the electrode layer 120 are separated by the first dielectric layer 130. The first dielectric layer 130 and the second dielectric layer 140 overlap with each other in the normal direction of the upper surface 110s. The second dielectric layer 140 is closer to the object 12 than the first dielectric layer 130. In some embodiments, a part of the second dielectric layer 140 can be permeated to the gaps of the first dielectric layer 130, therefore a part of the second dielectric layer 140 can overlap the first dielectric layer 130 in a direction parallel to the upper surface 110s (such as the first direction D1) as shown in FIG. 30. According to some embodiments, the first dielectric layer 130 has a thickness in a range of 20-500 μm, and the second dielectric layer 140 has a thickness in a range of 0.1-50 μm or 0.5-20 μm. If the second dielectric layer 140 is too thin, the second dielectric layer 140 will be unable to improve the electrostatic clamping force. If the second dielectric layer 140 is too thick, the second dielectric layer 140 will have free electrons during the process of generating induced charges. When the free electrons and the clamped object (such as silicon wafer) are conducted, damage or negative influence may occur.

In some embodiments, the base 100 may include ceramics and metal. The insulating layer 110 may include an oxide. The first dielectric layer 130 may be formed of aluminum oxide (Al₂O₃) or aluminum nitride (AlN), which has excellent insulating property to avoid the electrode layer 120 being short-circuited. Besides, aluminum oxide and aluminum nitride have a wide range of application. The material of the second dielectric layer 140 is different from that of the first dielectric layer 130, and the second dielectric layer 140 may include titanium, a group IVA element and oxygen. In some embodiments, the second dielectric layer 140 does not include aluminum oxide and aluminum nitride. To be more precisely, the second dielectric layer 140 is substantially consisted of titanium, at least one element of the IVA group and oxygen. In some embodiments, the second dielectric layer 140 is substantially consisted of titanium and the oxides of the group IVA element, or is substantially consisted of the oxide of titanium and a group IVA element, or the second dielectric layer 140 is substantially consisted of the oxide of titanium and the oxide of the group IVA element. The group IVA elements include carbon (C), silicon (Si), germanium (Ge), tin (Sn), lead (Pb), or a combination thereof. In the second dielectric layer 140, titanium and the sum of the titanium and the group IVA element have a molar % (e.g. Ti/(Ti+IVA)) of 5.0% to 95.0%. That is, if the mole number of titanium is M1 and the mole number of the group IVA element is M2, then the molar % of titanium is expressed as: (mol/mol)%=M1/(M1+M2)%. If the molar % of titanium is too low, this implies that the second dielectric layer 140 does not improve electrostatic clamping force much. If the molar % of titanium is too high, this implies that the second dielectric layer 140 will generate effects such as chalking, cracking, or peeling during the film forming process. In an embodiment, the second dielectric layer 140 may include one of the group IVA elements, but the present disclosure is not limited thereto. In other embodiments, the second dielectric layer 140 may include two of the group IVA elements. For example, the second dielectric layer 140 may include titanium dioxide and silicon dioxide, and has a composition of (SiO₂)_{X}(TiO₂)_{1-X}, wherein 0.05<X<0.95, and the structure is expressed as following Formula 1:

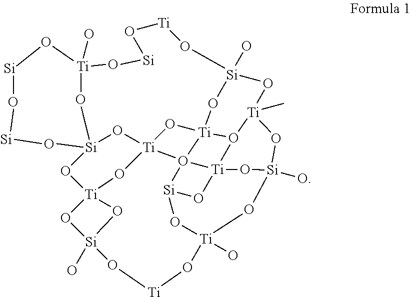

The electrostatic chuck 10 of the present disclosure is a Coulomb-type electrostatic chuck, and the clamping force of the electrostatic chuck 10 is proportional to the square of the dielectric constant (the k value) of the dielectric material (that is, the first dielectric layer 130 and the second dielectric layer 140) used in the electrostatic chuck 10. In an embodiment of the present disclosure, the first dielectric layer 130 includes aluminum oxide; the second dielectric layer 140 includes titanium and therefore has a dielectric constant larger than that of the first dielectric layer 130. According to a comparison example, it only has a first dielectric layer formed of aluminum oxide, but does not have a second dielectric layer (hereinafter referred as comparison example A). In comparison to the comparison example A, the second dielectric layer 140 of the present disclosure has a dielectric constant larger than that of the first dielectric layer 130, such that the overall dielectric constant of the dielectric material of the electrostatic chuck 10 can be increased, the electrostatic chuck 10 of the present disclosure can provide a larger clamping force.

In an embodiment, the first dielectric layer 130 can be formed by using a thermal spraying process, and the second dielectric layer 140 can be formed by using a sol-gel process. Since different manufacturing processes are used, the porosity of the first dielectric layer 130 is larger than the porosity of the second dielectric layer 140. For example, the porosity of the first dielectric layer 130 can be in a range of 0.5-15%. The porosity of the second dielectric layer 140 can be smaller than 0.5%. In other words, the structure of the second dielectric layer 140 is denser than the structure of the first dielectric layer 130. In comparison example A, the electrostatic chuck only has the first dielectric layer with a larger porosity, and after the electrostatic chuck is performed with a semiconductor process at a high temperature for a long duration of vacuum state, the water moisture which originally was absorbed in the gaps of the first dielectric layer is evaporated. Since the dielectric constant of water is lamer than the dielectric constant of aluminum oxide, the overall dielectric constant of the electrostatic chuck decreases, and the electrostatic chucking force (that is, the damping force) also decreases. Unlike comparison example A, in the present disclosure, the second dielectric layer 140 of the electrostatic chuck 10 covers the first dielectric layer 130, not only sealing the gaps of the first dielectric layer 130 to avoid the evaporation of the water moisture, but further resolving the decay of the electrostatic pressure which occurs at a high temperature for a long duration of vacuum state.

In comparison example B, in order to increase the clamping force of the electrostatic chuck, an inorganic material with a large dielectric constant (such as titanium dioxide or zirconium dioxide) is directly doped in the first dielectric layer formed of aluminum oxide, In the said method, the overall dielectric constant of the first dielectric layer is directly increased. If the concentration of the inorganic material with a large dielectric constant doped in the first dielectric layer is too high, the electrostatic chuck may generate conduction between electrodes and electrodes, between electrodes and the base, and between electrodes and the to-be-clamped object. Unlike comparison example B, in the present disclosure, the second dielectric layer 140 of the electrostatic chuck 10 is additionally formed on the first dielectric layer 130 and the insulating ability of the first dielectric layer 130 is not decreased, such that the dielectric constant of the overall electrostatic chuck 10 can be increased and the effect of electrostatic clamping force can be enhanced without triggering the said conduction.

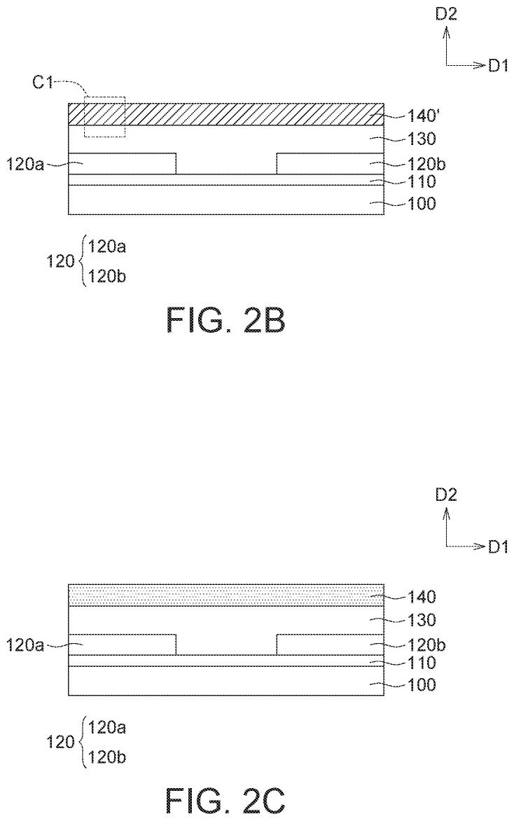

FIGS. 2A-2C are processes of a method for manufacturing an electrostatic chuck 10 according to an embodiment of the present disclosure,

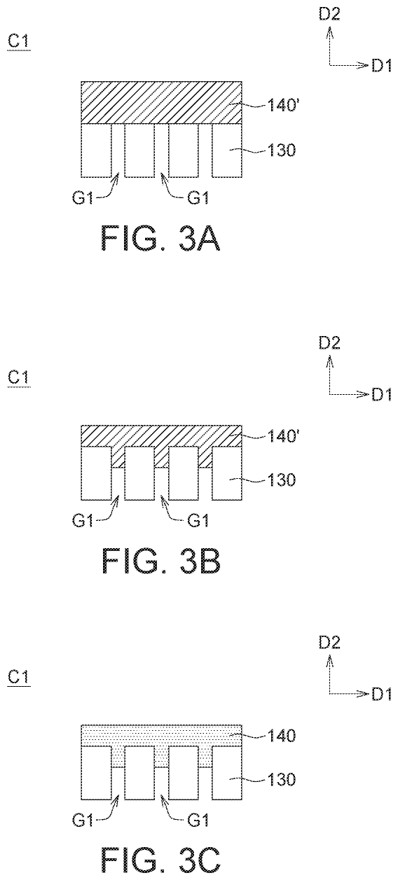

FIGS. 3A-3C are processes of a manufacturing method corresponding to a part C1 of the second dielectric layer 140 of FIG. 2B.

Refer to FIG. 2A. A base 100 is provided, and an insulating layer 110 and an electrode layer 120 are sequentially formed and stacked on the base 100. The base 100 can be a metal or ceramic base with pattern, circuit, cooling water and vent pipe structure designed on the surface. The insulating layer 110 can be formed by using a thermal spraying process. The electrode layer 120 is formed by using a screen printing process or a thermal spraying process. The electrode layer 120 comprises a first electrode 120a and a second electrode 120b. Then, a first dielectric layer 130 is formed on the insulating layer 110 by using a thermal spray process. The first dielectric layer 130 includes aluminum oxide (Al₂O₃). Thermal spraying process includes powder flame spraying, atmospheric plasma spraying, vacuum plasma spraying or arc spraying.

Refer to FIGS. 2B-2C. A second dielectric layer 140 is formed on the first dielectric layer 130 by using a sol-gel process. As indicated in FIG. 2B, the dielectric material 140′ in a liquid state (sol state) is coated on the first dielectric layer 130. The material of the dielectric material 140′ is different from the material of the first dielectric layer 130, and includes titanium, a group IVA element and oxygen. Then, the dielectric material 140′ in a sol state is cured and baked to form a second dielectric layer 140 in a solid state (gel state) as shown in FIG. 2C.

Refer to both FIGS, 2B and 3A. The first dielectric layer 130 includes a plurality of gaps G1, the dielectric material 140′ in a liquid state (sol state) is coated on the first dielectric layer 130 having gaps G1. Then, referring to FIG. 3B, the dielectric material 140′ in a liquid state (sol state) is permeated into the gaps G1. Referring to FIG. 3C, after the curing and baking steps are performed, the dielectric material 140′ in a sol state forms a second dielectric layer 140 in a solid state (gel state), and a part of the second dielectric layer 140 overlaps the first dielectric layer 130 in the first direction D1. Since a part of the second dielectric layer 140 is embedded in the first dielectric layer 130, the second dielectric layer 140 and the first dielectric layer 130 are well adhered and the second dielectric layer 140 will not be easily peeled from the first dielectric layer 130.

In comparison to the comparison example in which the second dielectric layer is formed by using a thermal spraying process, in the present disclosure, the second dielectric layer 140 is formed by using a sol-gel process and therefore has a smaller porosity (such as smaller than 0.5%), the structure has a larger density, and water moisture is less likely evaporated under the conditions of high temperature and vacuum state. Thus, the drop of the electrostatic pressure caused by the removal of water moisture can be avoided.

Generally speaking, the coating solution LT, which contains the oxide of titanium (such as titanium dioxide) and is manufactured by using a sol gel method, may easily form large particles and generate phenomena such as precipitation or colloidization. The stability of the coating solution LT is insufficient. Furthermore, after the coating solution LT is coated on the first dielectric layer disposed on the surface of the electrostatic chuck and then is cured and baked to form a film, powders may be generated or the film layer may be peeled off, making the formation and stability of the film unsatisfactory. In comparison to the comparison example in which the second dielectric layer includes titanium and oxygen but not group IVA elements, in the present disclosure, the second dielectric layer 140 includes titanium, oxygen and a group IVA element, which can modify the structure of the oxide of titanium and make the molecular size controllable, such that the coating solution (that is, the dielectric material 140 in a liquid state) can have better stability, and during the curing and baking step, the second dielectric layer 140 is less likely to generate powders or become peeled off, and therefore has a better performance in film formation.

The electrostatic chucks according to examples 1˜6 and comparison examples 1˜4 are exemplified below, and the damping force and film formation of each electrostatic chuck are tested. The structure of the electrostatic chuck of each of examples 1˜6 is identical to the structure of the electrostatic chuck 10 of FIG. 1, and the manufacturing process of the electrostatic chuck of examples 1˜6 is identical to that of the electrostatic chuck 10 of FIGS. 2A-2C. That is, in examples 1˜6, the electrostatic chuck comprises a base and an insulating layer, an electrode layer, a first dielectric layer and a second dielectric layer sequentially stacked on the base. The first dielectric layer is formed by using a thermal spray process, the material of the first dielectric layer includes aluminum oxide, and the first dielectric layer has a thickness in a range of 100 μm-110 μm; and the second dielectric layer is formed by using a sol gel method. The structure of the electrostatic chuck as indicated in comparison examples 2˜4 is similar to the structure of the electrostatic chuck 10. That is, the electrostatic chuck in comparison examples 2˜4 also includes a first dielectric layer and a second dielectric layer, the first dielectric layer is formed by using a thermal spray process, the material of the first dielectric layer includes also aluminum oxide, and the first dielectric layer has a thickness in a range of 100 μm-110 μm. In examples 1˜6 and comparison examples 2˜4, the material or/and usage of the second dielectric layer are not the same. In embodiments 1˜4, the second dielectric layer includes titanium, oxygen and silicon. In example 5, the second dielectric layer includes titanium, oxygen, silicon and carbon. In example 6, the second dielectric layer includes titanium, oxygen and tin. The structure of the electrostatic chuck of comparison example 1 is different from the structure of the electrostatic chuck 10 in that the electrostatic chuck of comparison example 1 does not include a second dielectric layer, but the first dielectric layer is also formed by using a thermal spray process, the material of the first dielectric layer also includes aluminum oxide, and the first dielectric layer has a thickness in a range of 100 μm-110 μm. Details of the method for manufacturing the second dielectric layer of the electrostatic chuck of each of examples 1˜6 and comparison examples 2˜4 are disclosed below.

### EXAMPLE 1

36 g of tetraethoxysilane (TEOS), 90 g of methyltriethoxysilane (MTES), 18 g of (3-glycidyloxypropyl) trimethoxysilane (GPTMS) and 36 g of 0.1N nitric add solution are mixed, and then are stirred and reacted at room temperature for 16 hours, then the mixed solution is reacted at 60° C. for 8 hours to form a solution A1.

2.76 g of 65-70% nitric acid and 7.6 g of ethanol are added to 10 g of deionized water, then the mixed solution is stirred for 20 minutes to form a catalytic solution T1. 8.5 g of titanium (IV)-butoxide (TBO) and 27.6 g of ethanol are mixed and stirred for 20 minutes, then the mixed solution is slowly added to the catalytic solution T1, and together is stirred at room temperature for 60 minutes to form a solution B1.

20 g of solution A1 (that is, silicon-containing solution) and 5 g of solution B1 (that is, titanium-containing solution) are mixed and then the mixed solution is stirred at room temperature for 16 hours to obtain a titanium silicon composite solution D1. Then, the titanium silicon composite solution D1 is coated on the first dielectric layer by a brushing method and is cured at 140° C. for 20 minutes and is further baked at 200° C. for 16 hours to form a second dielectric layer.

### EXAMPLE 2

A solution A2 and a solution B2 are respectively formed by using the same method for manufacturing the solution A1 and the solution B1 of example 1.

35g of solution A2 (that is, silicon-containing solution) and 15 g of solution B2 (that is, titanium-containing solution) are mixed and then the mixed solution is stirred at room temperature for 16 hours to obtain a titanium silicon composite solution D2. Then, the titanium silicon composite solution D2 is coated on the first dielectric layer by a brushing method and is cured at 140° C. for 20 minutes and is further baked at 200° C. for 16 hours to form a second dielectric layer.

### EXAMPLE 3

A solution A3 and a solution B3 are respectively formed by using the same method for manufacturing the solution A1 and the solution B1 of example 1.

30 g of solution A3 (that is, silicon-containing solution) and 20 g of solution B3 (that is, titanium-containing solution) are mixed and then the mixed solution is stirred at room temperature for 16 hours to obtain a titanium silicon composite solution D3. Then, the titanium silicon composite solution D3 is coated on the first dielectric layer by a brushing method and is cured at 140° C. for 20 minutes and is further baked at 200° C. for 16 hours to form a second dielectric layer.

### EXAMPLE 4

A solution A4 and a solution B4 are respectively formed by using the same method for manufacturing the solution A1 and the solution B1 of example 1.

20 g of solution A4 (that is, silicon-containing solution) and 20 g of solution B4 (that is, titanium-containing solution) are mixed and then the mixed solution is stirred at room temperature for 16 hours to obtain a titanium silicon composite solution D4. Then, the titanium silicon composite solution D4 is coated on the first dielectric layer by a brushing method and is cured at 140° C. for 20 minutes and is further baked at 200° C. for 16 hours to form a second dielectric layer.

The second dielectric layer of examples 1˜4 may include the structure as indicated in above-mentioned Formula 1.

### EXAMPLE 5

2 g of 3-(trimethoxysilyl)-propylmethacrylate (MSMA) are added to 20 g of n-butanol and then the mixed solution is stirred at room temperature for 30 minutes to form a solution A5.

27.8 g of titanium (IV)-butoxide are added to 40 g of n-butanol and then the mixed solution is stirred at room temperature for 30 minutes to form a solution B5. Then, 60 g of n-butanol, 1.12 g deionized water, and 1 g of 1N hydrochloric acid are mixed and then the mixed solution is stirred at room temperature for 30 minutes to form a solution T5.

The solution T5 is slowly added to the solution B5, which is still being stirred. After the mixed solution is stirred at room temperature for 60 minutes, the solution A5 is slowly added to the mixed solution and together are stirred at room temperature for 90 minutes, then the temperature is increased to 50° C.: and the mixed solution is stirred for 120 minutes to form a titanium silicon composite solution D5. Then, the titanium silicon composite solution D5 is coated on the first dielectric layer by a brushing method and is cured at 140° C. for 20 minutes and is further baked at 200° C. for 16 hours to form a second dielectric layer.

The second dielectric layer of example 5 may include the structure as indicated in the following Formula 2:

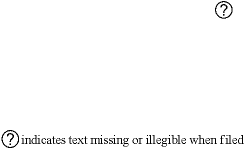

### EXAMPLE 6

11.28 g of water-containing stannous chloride (SnCl₂·2H₂O) are added to 46 g of ethanol , then the mixed solution is stirred at room temperature for 24 hours to form a solution A6.

2.76 g of 65-70% nitric acid and 7.6 g of ethanol are added to 10 g of deionized water, then the mixed solution is stirred for 20 minutes to form a catalytic solution T6. 8.5 g of titanium (IV)-butoxide and 27.6 g of ethanol are mixed and stirred for 20 minutes, then the mixed solution is slowly added to the catalytic solution T6, and together are stirred at room temperature for 60 minutes to form a solution B6.

5 g of the solution A6 (that is, tin-containing solution) and 5 g of the solution B6 (that is, titanium-containing solution) are mixed then the mixed solution is stirred at room temperature for 16 hours to obtain a titanium-tin composite solution D6. Then, the titanium-tin composite solution D6 is coated on the first dielectric layer by a brushing method and is cured at 140° C. for 20 minutes and is further baked at 200° C. for 16 hours to form a second dielectric layer.

The second dielectric layer of example 6 may comprise the structure as indicated in the following Formula 3:

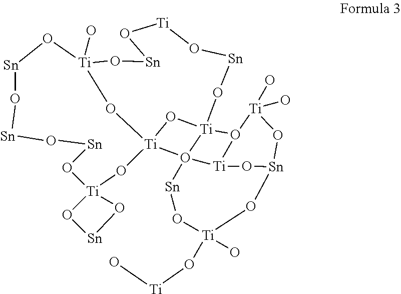

### Comparison example 2

36 g of tetraethoxysilane (TEAS), 90 g of methyltriethoxysilane (MTES), 18 g of (3-glycidyloxypropyl) trimethoxysilane (GPTMS) and 36 g of 0.1N nitric acid solution are mixed and then are stirred and reacted at room temperature for 16 hours. Then, the mixed solution is reacted at 60° C. for 8 hours to form a solution A12 The solution A12 is coated on the first dielectric layer by a brushing method and is cured at 140° C. for 20 minutes and is further baked at 200° C. for 16 hours to form a second dielectric layer.

### Comparison example 3

1 g of 3-(trimethoxysilyl)-propylmethacrylate (MSMA) is added to 20 g of n-butanol, then the mixed solution is stirred at room temperature for 30 minutes to form a solution A13.

27.8 g of titanium (IV)-butoxide are added to 40 g of n-butanol then the mixed solution is stirred at room temperature for 30 minutes to form a solution B13. 60 g of n-butanol, 1.12 g of deionized water, and 1 g of 1N hydrochloric acid are mixed, then the mixed solution is stirred at room temperature for 30 minutes to form a solution T13.

The solution T13 is slowly added to the solution B13, which is still being stirred. After the mixed solution is stirred at room temperature for 60 minutes, the solution A13 is slowly added to the mixed solution and together are stirred at room temperature for 90 minutes, then the temperature is increased to 50° C. and the mixed solution is stirred for 120 minutes to form a titanium silicon composite solution D13. Then, the titanium silicon composite solution D13 is coated on the first dielectric layer by a brushing method and is cured at 140° C. for 20 minutes and is further baked at 200° C. for 16 hours to form a second dielectric layer.

### Comparison Example 4

8.5 g of titanium (IV)-butoxide are added to 27.6 g of ethanol, then the mixed solution is stirred for 20 minutes to form a solution B14. Then, 2.76 g of 65-70% nitric acid and 7.6g of ethanol are added to 10 g of deionized water and together are stirred for 20 minutes to form a catalytic solution T14.

The catalytic solution T14 is slowly added to the solution B14 and together are stirred at room temperature for 60 minutes to form a solution D14. Then, the solution D14 is coated on the first dielectric layer by a brushing method and is cured at 140° C. for 20 minutes and then is further baked at 200° C. for 16 hours to form a second dielectric layer.

The materials, the features and the film formation state of the second dielectric layer of each of examples 1-6 and comparison examples 2-4 are illustrated in the following Table 1.

TABLE 1

| | Material and property of the second dielectric layer | | | | | |
|---|---|---|---|---|---|---|
| | | Precursor of | | | Film formation state of the | |
| | Precursor of | the group IVA | | Mole ratio of | second dielectric layer | Film formation state of the |
| | titanium/ | elements/ | Stability | titanium | following the curing step | second dielectric layer |
| | amount | amount | *1 | *2 | *3 | following the baking step *4 |
| Example 1 | TBO/0.75 g | TEOS: 4.0 g | No gelation | 7.95% | Structure is intact complete | Structure is intact complete |
| | | MTES: 10.0 g | for 7 days | | without deterioration | without deterioration |
| | | GPTMS: 2.0 g | | | | |
| Example 2 | TBO/2.26 g | TEOS: 7.0 g | No | 12.89% | Structure is intact complete | Structure is intact complete |
| | | MTES: 17.5 g | gelation | | without deterioration | without deterioration |
| | | GPTMS: 3.5 g | for 7 days | | | |
| Example 3 | TBO/3.01 g | TEOS: 6.0 g | No | 18.72% | Structure is intact complete | Structure is intact complete |
| | | MTES: 15 g | gelation | | without deterioration | without deterioration |
| | | GPTMS: 3 g | for 7 days | | | |
| Example 4 | TBO/3.01 g | TEOS: 4.0 g | No | 25.67% | Structure is intact complete | Structure is intact complete |
| | | MTES: 10.0 g | gelation | | without deterioration | without deterioration |
| | | GPTMS: 2.0 g | for 7 days | | | |
| Example 5 | TBO/27.8 g | MSMA: 2.0 g | No | 91.03% | Structure is intact complete | Structure is intact complete |
| | | | gelation | | without deterioration | without deterioration |
| | | | for 30 days | | | |
| Example 6 | TBO/4.9 g | SnCl2•2H₂O: | No | 76.82% | Structure is intact complete | Structure is intact complete |
| | | 1 g | gelation | | without deterioration | without deterioration |
| | | | for 7 days | | | |
| Comparison | N/A | | | | | |
| example 1 | | | | | | |
| Comparison | N/A | TEOS: 4.0 g | No gelation | 0% | Structure is intact complete | Structure is intact complete |
| example 2 | | MTES: 10.0 g | for 30 days | | without deterioration | without deterioration |
| | | GPTMS: 2.0 g | | | | |
| Comparison | TBO/27.8 g | MSMA: 1.0 g | No | 95.3% | Film layer cracks and peels off | Film layer cracks and peels off |
| example 3 | | | gelation | | | |
| | | | for 30 days | | | |
| Comparison | TBO/8.5 g | N/A | Gelation | 100% | Powders precipitate/ | Powders precipitate/ |
| example 4 | | | after 3 days | | film cannot be formed | film cannot be formed |

*1: Solutions D1-D6, A12, D13 and D14 are placed at room temperature, and respective solution stability is observed.
*2: If the mole number of titanium is M1 and the mole number of the group IVA elements is M2, then the mole ratio of titanium is expressed as: (mol/mol) = M1/(M1 + M2)
*3: cured at 140° C. for 20 minutes
*4: Baked at 200° C. for 16 hours

As illustrated in Table 1, since each of the solutions D1-D6 for forming the second dielectric layer of examples 1˜6 of the present disclosure includes the group IVA elements which can stabilize the structure of the oxide of titanium, the second dielectric layer possesses excellent stability, and will not generate any changes (gelation) after having been placed at room temperature for 7 days, and the structure is still intact complete without deterioration after the curing and baking step is performed. Conversely, since the solution D14 for forming the second dielectric layer of comparison example 4 does not include the group IVA elements which can stabilize the structure of the oxide of titanium, the second dielectric layer has poor stability, is gelatinized after 3 days, and precipitate powders and cannot form film after the curing and baking step is performed. Additionally, since the mole ratio of titanium of comparison example 3 is too large (larger than 95%), the film layer will crack and peel off after the curing and baking step is performed.

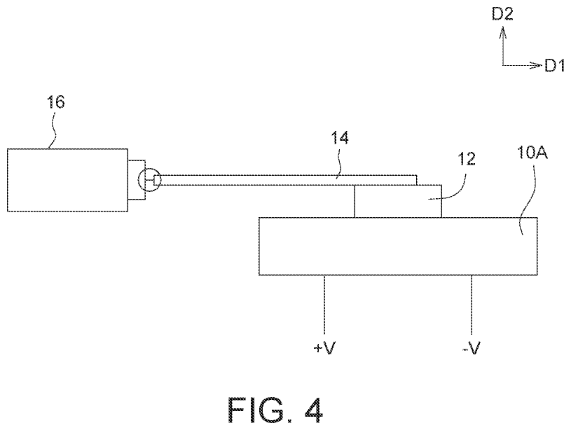

FIG. 4 is a schematic diagram of an assembly equipment for testing the electrostatic clamping force of an electrostaticchuck 10A.

Refer to FIG. 4. An object 12 to be clamped (such as glass or wafer) is placed above the electrostatic chuck 10A. The electrostatic chuck 10A can be realized by the electrostatic chuck of any embodiment or any comparison example of the present disclosure. One end of the heat-resistant tape 14 is fixed on the electrostatic chuck 10A, and the other end of the heat-resistant tape 14 is connected to a tension meter 16 (such as the tension meter manufactured by the Calitech Co., Ltd.).After a positive voltage +V (such as +1200V) and a negative voltage −V (such as 31 1200V) are respectively applied to the electrostatic chuck 10A, the electrostatic damping force generated by the electrostatic chuck 10A is measured by using the tension meter 16.

The electrostatic clamping force of the assembly equipment of FIG. 4 is measured according to the conditions of examples 2 and 5 and comparison examples 1, 2 and 4 , and the results are listed in Table 2.

TABLE 2

| | Electrostatic clamping force test (gf/cm²) | | | |
|---|---|---|---|---|
| | 25° C. initial | 60° C. | 12 h vacuum | 76 h vacuum |
| | electrostatic | electrostatic | (<10torr) | (<10torr) |
| | clamping | clamping | electrostatic | electrostatic |
| | force | force | clamping force | clamping force |
| example 2 | 11.6 | 4.8 | 7.0 | 3.8 |
| example5 | 13.3 | 7.3 | 10.9 | 6.3 |
| Comparison | 8.0 | 1.8 | 2.0 | — |
| example 1 | | | | |
| Comparison | 4.3 | 1.3 | — | — |
| example 2 | | | | |
| Comparison | Film cannot | Film cannot | Film cannot | Film cannot |
| example 4 | be formed/ | be formed/ | be formed/ | be formed/ |
| | Cannot be | Cannot be | Cannot be | Cannot be |
| | tested | tested | tested | tested |

As illustrated in Table 2, the electrostatic chuck of each of the examples 2 and 5 of the present disclosure includes a second dielectric layer having a densed structure capable of sealing the gaps of the first dielectric layer, and the second dielectric layer further includes titanium having a high dielectric constant. Unlike the comparison example 1, in which the electrostatic chuck only includes a first dielectric layer and the electrostatic damping force greatly deteriorates due to the evaporation of water moisture, in the examples 2 and 5 of the present disclosure the electrostatic chuck has a large electrostatic damping force under the condition of 25° C. and 60° C., and still can reach the electrostatic clamping force of 3.8 gf/cm² and 6.3 gf/cm² even in a vacuum environment for a long duration (76 hours). Besides, the second dielectric layer of examples 2 and 5 of the present disclosure includes titanium having a high dielectric constant, and therefore provides a larger electrostatic clamping force than the second dielectric layer of comparison example 2 which does not include titanium.

According to an embodiment of the present disclosure, an electrostatic chuck and a method for manufacturing the same are provided. The electrostatic chuck comprises a base and an insulating layer, an electrode layer, a first dielectric layer and a second dielectric layer sequentially stacked on the base. The first dielectric layer comprises aluminum oxide (Al₂O₃) or aluminum nitride (AlN), The material of the second dielectric layer is different from the material of the first dielectric layer, and the second dielectric layer includes titanium, a group IVA element and oxygen. Unlike the comparison example in which the electrostatic chuck includes only the first dielectric layer formed of aluminum oxide or the second dielectric layer of the electrostatic chuck which does not include titanium, in the present disclosure, the second dielectric layer of the electrostatic chuck includes titanium, such that the electrostatic chuck has a larger overall dielectric constant and can provide a larger electrostatic clamping force. Moreover, in comparison to the electrostatic chuck of the comparison example which does not include a second dielectric layer, the electrostatic chuck of the present disclosure includes a second dielectric layer, which seals the gaps of the first dielectric layer and avoids the water moisture being evaporated due to the high temperature and long duration of vacuum state in the semiconductor process and reducing the absorption ability of the electrostatic chuck. Therefore, the electrostatic chuck of the present disclosure can increase the electrostatic clamping force, the lifespan can be extended and the fluency of the semiconductor process can be increased.

While the disclosure has been described by way of example and in terms of the preferred embodiment(s), it is to be understood that the disclosure is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. An electrostatic chuck, comprising:
a base; and
an insulating layer, an electrode layer, a first dielectric layer and a second dielectric layer sequentially stacked on the base,
wherein the first dielectric layer is formed of aluminum oxide (Al₂O₃) or aluminum nitride (AlN), a material of the second dielectric layer is different from a material of the first dielectric layer, and the second dielectric layer comprises titanium, a group IVA element and oxygen.

2. The electrostatic chuck according to claim 1, wherein the group IVA element comprises carbon (C), silicon (Si), germanium (Ge), tin (Sn), lead (Pb), or a combination thereof.

3. The electrostatic chuck according to claim 1, wherein the titanium and the sum of the titanium and the group IVA element have a molar % of 5.0% to 95.0%.

4. The electrostatic chuck according to claim 1, wherein the first dielectric layer having a thickness of 20 μm to 500 μm.

5. The electrostatic chuck according to claim 1 wherein the second dielectric layer having a thickness of 0.1 μm to 50 μm.

6. The electrostatic chuck according to claim 1, wherein the insulating layer has an upper surface, the first dielectric layer overlaps the second dielectric layer along a normal direction of the upper surface.

7. The electrostatic chuck according to claim 1, wherein the second dielectric layer and the electrode layer are separated by the first dielectric layer.

8. The electrostatic chuck according to claim 1, wherein a porosity of the first dielectric layer is larger than a porosity of the second dielectric layer.

9. A method for manufacturing an electrostatic chuck, comprising following steps:
providing a base;
sequentially forming and stacking an insulating layer and an electrode layer on the base;
forming a first dielectric layer on the insulating layer by using a thermal spraying process;
forming a second dielectric layer on the first dielectric layer by using a sol-gel process,
wherein the first dielectric layer is formed of aluminum oxide (Al₂O₃) or aluminum nitride (AlN), a material of the second dielectric layer is different from a material of the first dielectric layer, and the second dielectric layer comprises titanium, a group IVA element and oxygen.

10. The method for manufacturing an electrostatic chuck according to claim 9, wherein the thermal spraying process comprises powder flame spraying, atmospheric plasma spraying, vacuum plasma spraying or arc spraying.

11. The method for manufacturing an electrostatic chuck according to claim 9, wherein the group IVA element comprises carbon (C), silicon (Si), germanium (Ge), tin (Sn), lead (Pb), or a combination thereof.

12. The method for manufacturing an electrostatic chuck according to claim 9, wherein the titanium and the sum of the titanium and the group IVA element have a molar % of 5.0% to 95.0%.
